(19) United States
(12) Patent Application Publication
(10) Pub. No.: US 2012/0001310 A1
(43) Pub. Date: Jan. 5, 2012

(54) PACKAGE FOR SEMICONDUCTOR DEVICE, AND METHOD OF MANUFACTURING THE SAME AND SEMICONDUCTOR DEVICE

(75) Inventors: Masanori Nishino, Kyoto (JP); Hiroshi Horiki, Kyoto (JP)

(73) Assignee: PANASONIC CORPORATION, Osaka (JP)

(21) Appl. No.: 13/165,437

(22) Filed: Jun. 21, 2011

(30) Foreign Application Priority Data
Jun. 22, 2010 (JP) 2010-141126
May 23, 2011 (JP) 2011-114258

(51) Int. Cl. H01L 23/495; H01L 21/60

(52) U.S. Cl. 257/676; 438/123; 257/E21.506; 257/E23.042

(57) ABSTRACT

A package for a semiconductor device according to the present invention includes at least one through hole 6 provided on at least one of lead frames 1 and 2. Thus when resin is injected to form a mounting region 4 of a semiconductor element while holding the lead frames 1 and 2, the resin can be injected from the back sides of the lead frames 1 and 2 through the through hole 6 serving as a resin flow path, thereby shortening the resin flow path and suppressing the occurrence of portions unfilled with the resin and poor appearances.

### FIELD OF THE INVENTION

The present invention relates to a package for a semiconductor device, the package containing resin on lead frames, the resin forming the mounting region of a semiconductor element while holding the lead frames.

### BACKGROUND OF THE INVENTION

Referring to FIGS. 6A to 6C, the following will describe a package for a semiconductor device according to the related art.

FIGS. 6A to 6C are schematic drawings showing the configuration of the package for a semiconductor device according to the related art. Arrows in the drawings indicate the paths of flowing resin during injection of resin. FIG. 6A is a top view. FIG. 6B shows a cross-sectional structure taken along line X-X′ of FIG. 6A, as an explanatory drawing of a resin injection process. FIG. 6C is a side perspective view taken along direction A of FIG. 6B.

As shown in FIGS. 6A to 6C, the package for a semiconductor device according to the related art includes: a lead frame 21 including the mounting region of a semiconductor element on inner leads; a lead frame 22 including a connected region to a semiconductor device on inner leads; and a resin part 23 that holds the lead frames 21 and 22 and has an opening corresponding to the mounting region of the semiconductor element.

In the formation of the resin part 23, the lead frames 21 and 22 are fit into a die, resin is injected in this state into the die from the backside of the mounting region of the semiconductor element between the lead frames 21 and 22, and the space of the die is filled with the resin, so that the predetermined resin part 23 is formed.

### DISCLOSURE OF THE INVENTION

In the case where the resin part 23 is formed by injecting resin from the backside between the lead frames 21 and 22 according to the related art, unfortunately, it is necessary to feed the injected resin up to the top surfaces of the lead frames 21 and 22 after passing the resin through the sides of the lead frames 21 and 22, causing a long and limited flow path, portions unfilled with resin, and a poor appearance on the package for a semiconductor device. These problems have become more noticeable because the resin part 23 has been reduced in size and the resin flow path has been reduced in width in response to the need for smaller and thinner packages for semiconductor devices.

The present invention has been devised to solve the problems. An object of the present invention is to suppress the occurrence of portions unfilled with resin and poor appearances.

In order to attain the object, a package for a semiconductor device according to the present invention includes: at least one first lead frame having an element mounting region on the major surface; at least one second lead frame that has a connected region on the major surface and is electrically isolated; at least one through hole that is provided on at least one of the first lead frame and the second lead frame and penetrates the major surface and the back side of the lead frame with respect to the major surface; a resin part formed on the major surfaces of the first lead frame and the second lead frame so as to open the element mounting region and the connected region; and holding resin provided at least partially on the sides of the first and second lead frames with respect to the major surfaces, in a gap between the first and second lead frames, and in the through hole, wherein the resin part covers at least a part of the through hole, and the resin part and the holding resin are made of the same material.

Preferably, the holding resin is only provided at least partially on the sides, in the gap, and in the through hole.

Preferably, the package for a semiconductor device includes a first step provided around the through hole to have a thin portion on the lead frame.

Preferably, the package for a semiconductor device includes a second step provided at least partially on the sides and around the gap to have a thin portion on the lead frame.

One of the first step and the second step may include discontinuously formed steps.

Preferably, one of the first step and the second step includes a continuously formed step.

Preferably, the holding resin exposed from the gap between the first and second lead frames in the opening of the resin part has a surface including asperities.

The asperities may include projections.

The asperities may include recesses.

The asperities may include at least one groove.

The resin part may be a reflector and the package may be a package for an optical semiconductor device.

A method of manufacturing a package for a semiconductor device according to the present invention includes: a lead frame processing step of forming at least one through hole on a lead frame, the through hole penetrating the major surface of the lead frame and the back side of the lead frame with respect to the major surface; a die step of placing the lead frame in a die; and a resin injecting step of injecting resin into the die, wherein the resin is injected onto the major surface of the lead frame at least through the through hole.

Preferably, in the lead frame processing step, a step is additionally formed around the through hole to have a thin portion on the lead frame.

The step may be formed by coining.

A semiconductor device according to the present invention includes: the package for a semiconductor device; a semiconductor element mounted on the element mounting region; a conductive material electrically connecting the semiconductor element and the connected region; and molding resin that molds the inside of the opening of the resin part.

Moreover, a semiconductor device includes: the package for a semiconductor device; an optical semiconductor element mounted on the element mounting region; a conductive material electrically connecting the optical semiconductor element and the connected region; and translucent resin that molds the inside of the opening of the reflector, wherein the semiconductor device is an optical semiconductor device.

### BRIEF DESCRIPTION OF THE DRAWINGS

FIG. 1A shows the configuration of a package for a semiconductor device according to a first embodiment;

FIG. 1B shows the configuration of the package for a semiconductor device according to the first embodiment;

FIG. 1C shows the configuration of the package for a semiconductor device according to the first embodiment;

FIG. 2A is a process sectional view showing a manufacturing process of a package for a semiconductor device according to the present invention;

FIG. 2B is a process sectional view showing the manufacturing process of the package for a semiconductor device according to the present invention;

FIG. 2C is a process sectional view showing the manufacturing process of the package for a semiconductor device according to the present invention;

FIG. 2D is a process sectional view showing the manufacturing process of the package for a semiconductor device according to the present invention;

FIG. 2E is a process sectional view showing the manufacturing process of the package for a semiconductor device according to the present invention;

FIG. 3A shows the configuration of a package for a semiconductor device according to a second embodiment;

FIG. 3B shows the configuration of the package for a semiconductor device according to the second embodiment;

FIG. 3C shows the configuration of the package for a semiconductor device according to the second embodiment;

FIG. 3D shows the configuration of the package for a semiconductor device according to the second embodiment;

FIG. 3E shows the configuration of the package for a semiconductor device according to the second embodiment;

FIG. 3F shows the configuration of the package for a semiconductor device according to the second embodiment;

FIG. 4A shows the configuration of resin between lead frames in a package for a semiconductor device according to a third embodiment;

FIG. 4B shows the configuration of the resin between the lead frames in the package for a semiconductor device according to the third embodiment;

FIG. 4C shows the configuration of the resin between the lead frames in the package for a semiconductor device according to the third embodiment;

FIG. 5A shows the configuration of a semiconductor device according to a fourth embodiment;

FIG. 5B shows the configuration of the semiconductor device according to the fourth embodiment;

FIG. 6A is a schematic drawing showing the configuration of a package for a semiconductor device according to the related art;

FIG. 6B is a schematic drawing showing the configuration of the package for a semiconductor device according to the related art; and

FIG. 6C is a schematic drawing showing the configuration of the package for a semiconductor device according to the related art.

### DESCRIPTION OF THE EMBODIMENTS

### First Embodiment

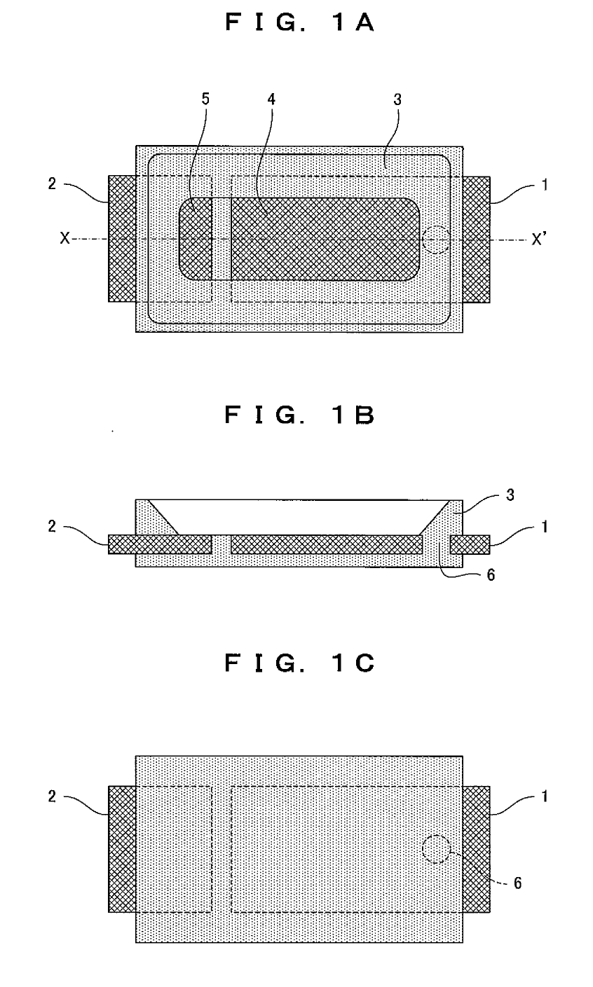

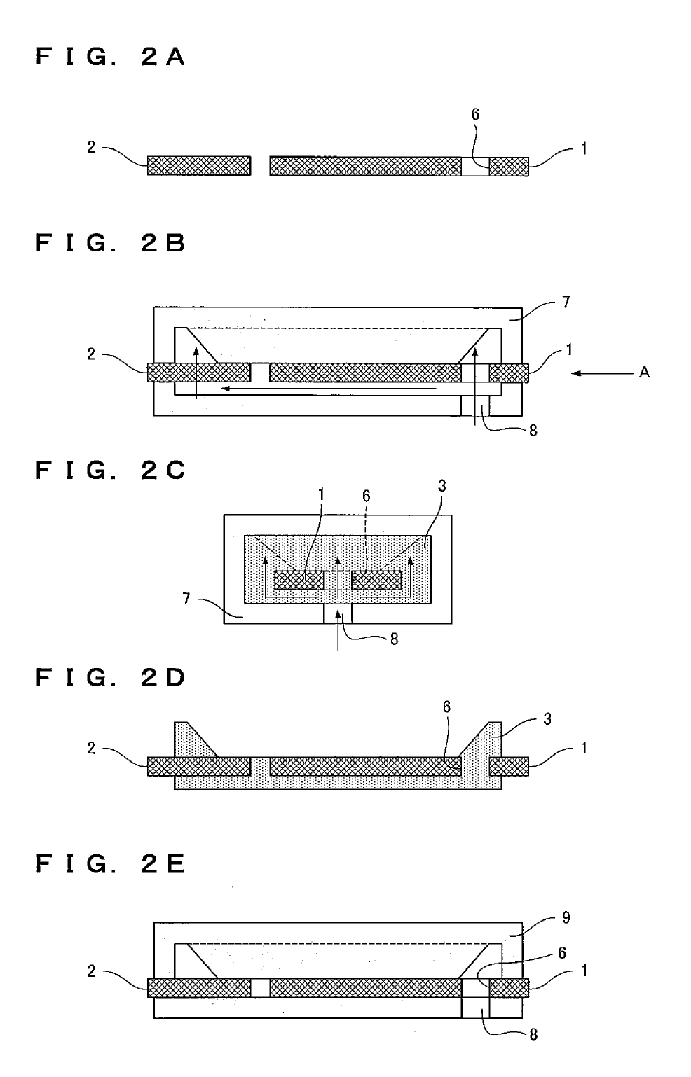

First, referring to FIGS. 1A to 1C and 2A to 2E, the following will describe the configuration of a package for a semiconductor device according to a first embodiment.

FIGS. 1A to 1C show the configuration of the package for a semiconductor device according to the first embodiment. FIG. 1A is a top view, FIG. 1B is a cross-sectional view taken along line X-X′ of FIG. 1A, and FIG. 1C is a back view. FIGS. 2A to 2E are process sectional views showing the manufacturing process of the package for a semiconductor device according to the present invention.

In FIGS. 1A to 1C, reference numeral 1 denotes a lead frame including a mounting region 4 of a semiconductor element on inner leads, reference numeral 2 denotes a lead frame including a connected region 5 to a semiconductor device on the inner leads, reference numeral 3 denotes a resin part that holds the lead frame 1 and the lead frame 2 and surrounds the mounting region 4 and the connected region 5 to protect the regions, and reference numeral 6 denotes a through hole provided on the lead frame 1. In the package for a semiconductor device according to the present invention, the lead frames 1 and 2 are held by the resin part 3 and resin on the sides and gap of the lead frames, and the mounting region 4 and the connected region 5 are opened by the resin part 3. A feature of the present invention is the provision of at least one through hole 6 in the forming region of the resin part 3 on one or both of the lead frames 1 and 2.

Since the through hole 6 is provided on the lead frame 1, when the resin part 3 is formed with a die, resin flows not only to the sides of the lead frames 1 and 2 but also to the top surfaces of the lead frames 1 and 2 through the through hole 6 serving as a resin flow path. Thus the resin flow path can be shortened and the occurrence of portions unfilled with resin can be suppressed.

Moreover, the through hole 6 can be reliably filled with resin, so that the lead frame 1 can be firmly held by the resin in the through hole 6.

In FIGS. 1A to 1C, the package for a semiconductor device with two terminals includes the single lead frame 2. Multiple lead frames 2 may be provided. Furthermore, the through hole 6 may be provided on the lead frame 2 or each of the lead frames 1 and 2 and the lead frame may include any number of through holes 6. The through hole 6 provided on the lead frame 2 can improve the holding power of the lead frame 2 and the efficiency of injecting resin into the resin part 3.

Referring to FIGS. 2A to 2E, the following will describe a method of manufacturing the package for an optical semiconductor device according to the present invention.

First, as shown in FIG. 2A, the lead frames 1 and 2 are formed that include at least one through hole 6 in the forming region of the resin part 3.

Next, as shown in FIG. 2B, the lead frames 1 and 2 are placed in a die 7 for forming the resin part 3. In this state, resin is injected from a resin inlet 8 of the die 7. The injected resin passes through a space in the die 7 and the through hole 6 formed on the lead frame, so that the forming region of the resin part 3 is filled with the resin. Since the resin is injected through the through hole 6 provided on the lead frame (see FIG. 2C, a schematic view taken along direction A), as compared with the case where resin is injected up to the top surfaces of the lead frames 1 and 2 after passing through the sides of the lead frames 1 and 2 in the space of the die 7, it is possible to shorten the resin flow path and suppress the occurrence of portions unfilled with resin, accurately forming the resin part 3.

Finally, as shown in FIG. 2D, the die 7 is removed after the resin is cured. Thus the package for a semiconductor device is completed in which the resin part 3 is provided on the lead frames 1 and 2 and the lead frames 1 and 2 are held at least by the resin part 3, resin in the through hole 6, resin on the sides of the lead frames 1 and 2, and resin in the gap between the lead frames 1 and 2.

In this explanation, the resin is also applied to the backsides of the lead frames 1 and 2 with respect to the element mounting surface. As long as the lead frames 1 and 2 can be sufficiently held, the backsides of the lead frames 1 and 2 may be uncoated with resin to reduce the thickness of the package for a semiconductor device.

In this case, the die 7 of FIG. 2B is replaced with a die 9 of FIG. 2E, so that a package for a semiconductor device can be formed with the backside uncoated with resin.

### Second Embodiment

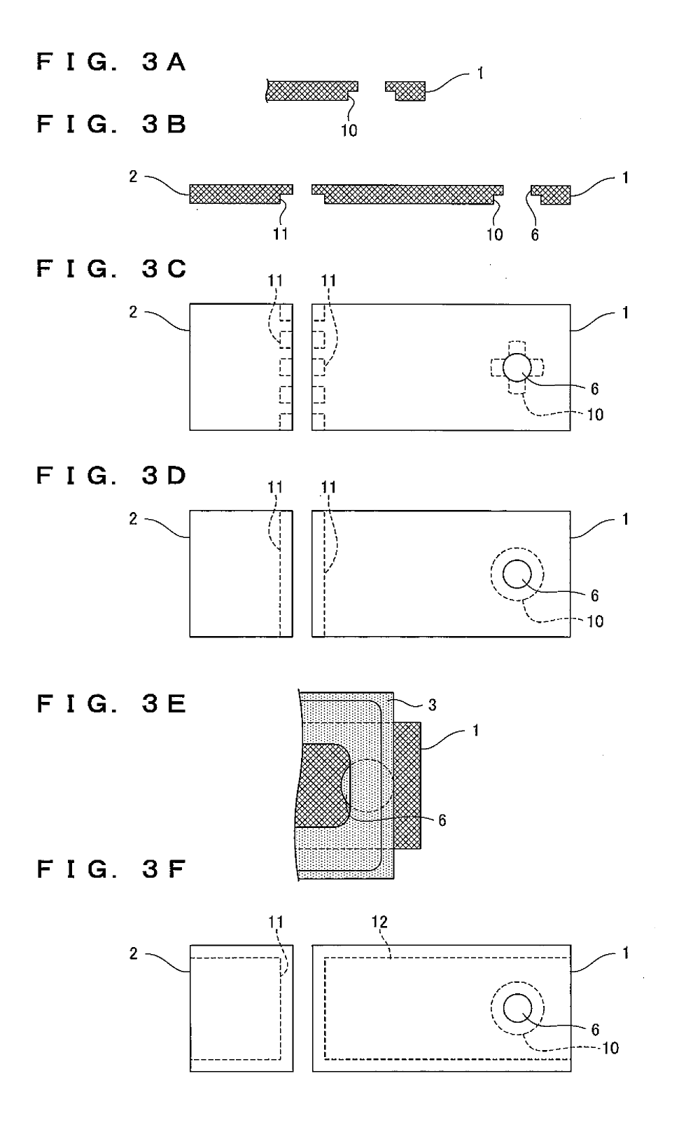

Referring to FIGS. 3A to 3F, the following will describe the configurations of a package for a semiconductor device according to a second embodiment.

FIGS. 3A to 3F show the configurations of the package for a semiconductor device and structural examples of steps according to the second embodiment.

A feature of the package for a semiconductor device according to the second embodiment is a step 10 provided on the through hole 6 of the package for a semiconductor device according to the first embodiment. The provision of the step 10 secures a resin flow path. Moreover, the holding powers of the lead frames 1 and 2 with resin can be improved by the anchor effect of the step 10 and an increased contact area between the lead frames 1 and 2 and the resin.

The configurations of the package for a semiconductor device will be described below in accordance with the drawings.

As shown in FIG. 3A, the step 10 is provided around the through hole 6 on the lead frame 1, so that the lead frame 1 has a thin portion around the through hole 6. The step 10 provided around the through hole 6 on the lead frame 1 is pressed into resin while securing a resin flow path, so that the lead frame 1 can be more effectively held by the resin part 3 with the anchor effect of the step 10.

As shown in FIG. 3B, in addition to the step 10 provided around the through hole 6, a step 11 may be provided on a part where the lead frames 1 and 2 are opposed to each other. Since the step 11 is provided on the part where the lead frames 1 and 2 are opposed to each other, the lead frames 1 and 2 can be more effectively held by resin with the anchor effects of the steps 10 and 11.

As shown in FIG. 3C, the steps 10 and 11 may be discontinuously formed around the through hole 6 and on the part where the lead frames 1 and 2 are opposed to each other, so that the lead frames 1 and 2 can be more effectively held by resin. Moreover, the steps 10 and 11 may be continuously formed as shown in FIG. 3D to further extend a resin flow path while improving the holding effect.

The steps 10 and 11 provided thus can improve the effect of holding the lead frames 1 and 2 and reduce the need for providing the resin part 3 on the backsides of the lead frames 1 and 2. Thus resin on the backsides of the lead frames 1 and 2 can be eliminated and the package for a semiconductor device can be easily reduced in thickness. In FIGS. 1A to 1C, the through hole 6 is formed in the forming region of the resin part 3. As shown in FIG. 3E, the through hole 6 may be extended out of the forming region of the resin part 3. Since the through hole 6 has an extended area, a contact area between the lead frame 1 and the resin increases and a larger holding power can be expected.

As shown in FIG. 3F, a step 12 may be continuously provided at least in the forming region of the resin part 3 around the lead frames 1 and 2. The provision of the step 12 allows the resin part 3 to more effectively hold the lead frames 1 and 2. Thus it is possible to further reduce the need for resin on the backsides of the lead frames 1 and 2, easily reducing the thickness of the package for a semiconductor device. Furthermore, the step 12 may be provided around the lead frames 1 and 2 to extend a resin flow path around the lead frames 1 and 2, improving the flowability of resin in the through hole 6, between the lead frames 1 and 2, and around the lead frames 1 and 2.

The steps 10, 11, and 12 may be formed by any methods including coining and etching.

The manufacturing process of the package for a semiconductor device is similar to that of the explanation of the first embodiment illustrated in FIGS. 2A to 2E.

The packages for a semiconductor device according to the first and second embodiments can be used as packages for an optical semiconductor device by replacing the resin part 3 on the top surfaces of the lead frames 1 and 2 with a reflector. In this case, it is preferable that the reflector is made of resin having a high light reflectance or a reflector surface on an element mounting surface is coated with a material having a high light reflectance, improving luminous efficiency. Moreover, the reflector surface on the element mounting surface is preferably inclined to the element mounting surface to improve the luminous efficiency.

### Third Embodiment

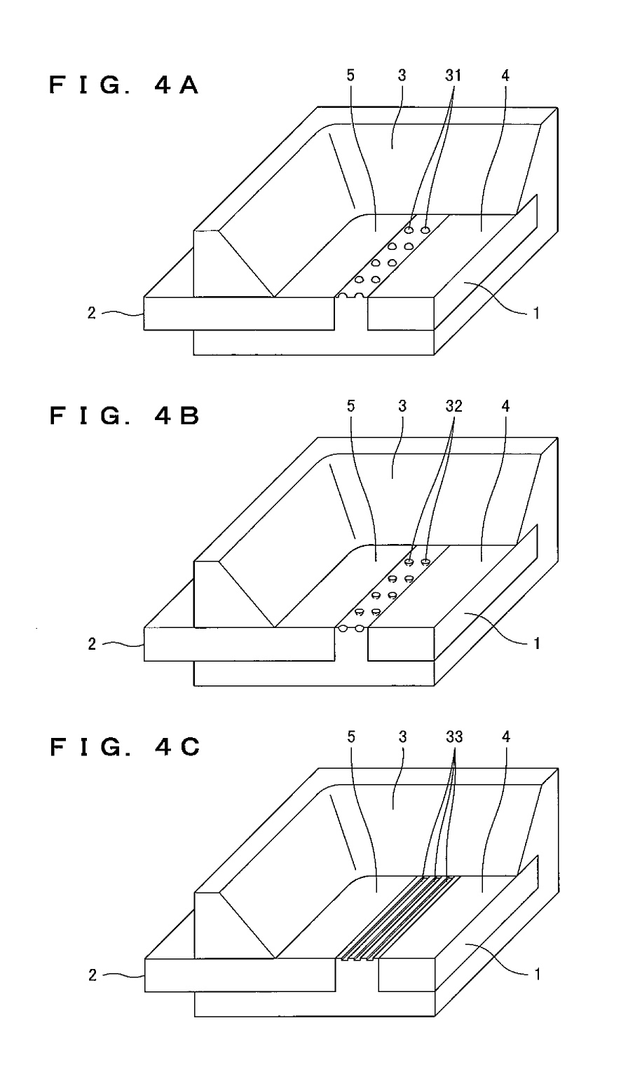

Referring to FIGS. 4A to 4C, the following will describe the configurations of a package for a semiconductor device according to a third embodiment.

FIGS. 4A to 4C show the configurations of resin between lead frames of the package for a semiconductor device according to the third embodiment. FIG. 4A is a perspective view illustrating the main part including projecting portions as asperities. FIG. 4B is a perspective view illustrating the main part including recessed portions as asperities. FIG. 4C is a perspective view illustrating the main part including grooves as asperities.

A feature of the package for a semiconductor device according to the third embodiment is the formation of asperities on an exposed surface between the lead frames 1 and 2 in the resin part 3 of the package for a semiconductor device according to the first or second embodiment.

As shown in FIGS. 4A to 4C, the resin part 3 surrounds the mounting region 4 on the surface of the lead frame 1 and the connected region 5 on the surface of the lead frame 2, is formed between the lead frames 1 and 2 and in a through hole, and is exposed, between the lead frames 1 and 2, from a surface on which the mounting region 4 and the connected region 5 are formed. The asperities are formed at least on the surface of an exposed region of the resin part 3 between the lead frames 1 and 2. In the case where a semiconductor device is mounted in the package for a semiconductor device and the regions surrounded by the resin part 3 are molded with molding resin while suppressing the occurrence of portions unfilled with the resin and poor appearances, the asperities formed on the exposed surface of the resin part 3 increase a contact area between the resin part 3 and the molding resin and improve adhesion between the resin part 3 and the molding resin, thereby preventing the molding resin from peeling off and reliably molding the package with the molding resin.

The asperities may be specifically shaped like, for example, protrusions 31 (FIG. 4A), recesses 32 (FIG. 4B), or at least one groove 33 formed in any directions (FIG. 4C) including a direction parallel to a side of the lead frame 1, the side being opposed to the lead frame 2, a direction orthogonal to the side of the lead frame 1, and combined directions. Alternatively, the protrusions 31, the recesses 32, and the groove 33 may be combined. The protrusions 31 or the recesses 32 may have any shapes including a spherical surface, a prism, and a pyramid, or these shapes may be combined. The protrusions 31 or the recesses 32 may have any sizes and may be uniform or varied in size. Moreover, the protrusions 31 or the recesses 32 may be regularly or irregularly arranged. The grooves 33 may have any sizes and vary in length, width, and depth. In the case where the through hole 6 is exposed in the opening of the resin part 3 (see FIG. 3E), asperities may be similarly formed on the surface of the resin part 3 in the through hole 6 (see FIG. 3E) exposed from the resin part 3, thereby improving adhesion between the injected molding resin and the resin part 3. FIGS. 4A to 4C show the provision of the asperities on the exposed resin part 3 of the package for a semiconductor device according to the first embodiment. The resin part 3 exposed between the lead frames 1 and 2 with the steps 11 may include the asperities of FIGS. 4A to 4C.

The die 7 of FIG. 2B or the die 9 of FIG. 2E is shaped to form the asperities, so that the asperities can be formed concurrently with the formation of resin that holds the lead frames 1 and 2, for example, the resin part 3 and resin in the through hole 6. The asperities may be formed by processing such as cutting and etching after the formation of the resin part 3.

### Fourth Embodiment

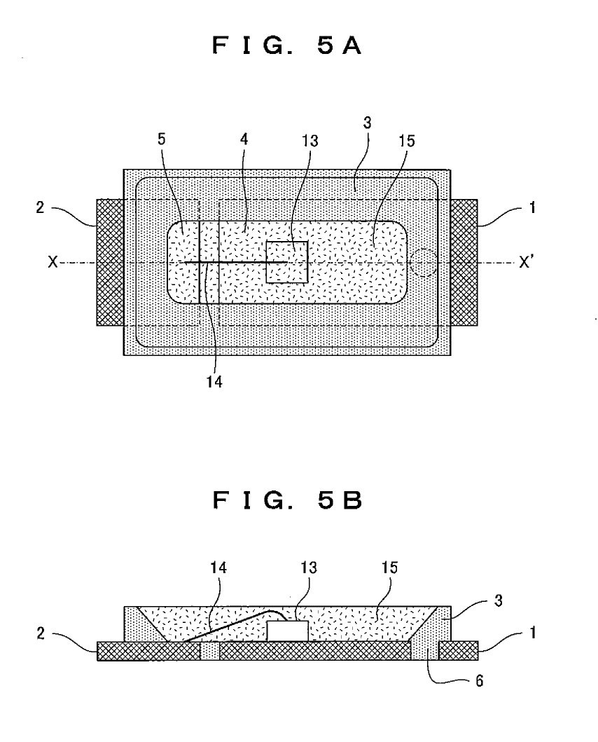

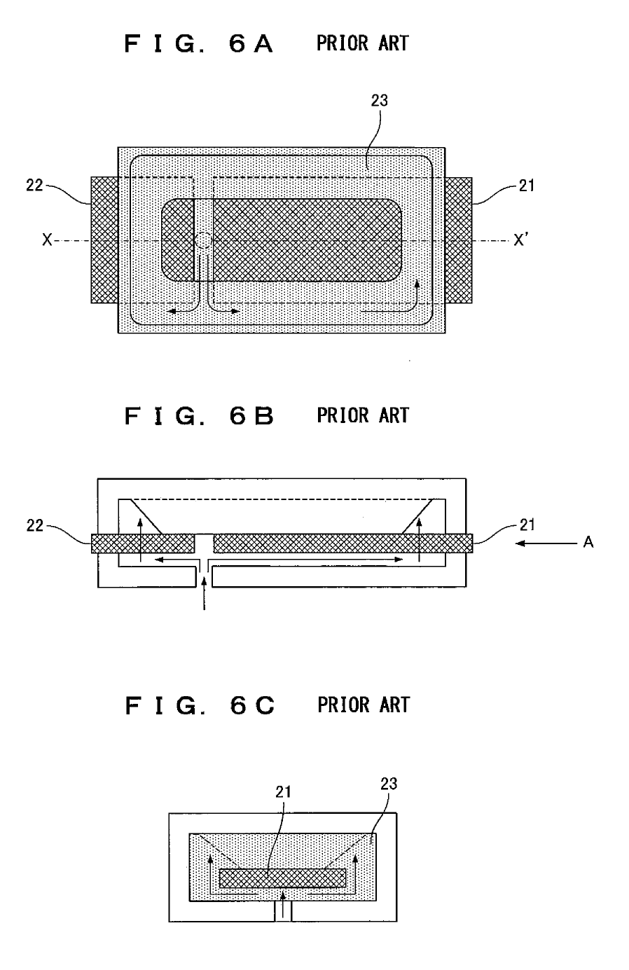

Referring to FIGS. 5A and 5B, the following will describe the configuration of a semiconductor device using the packages for a semiconductor device according to the first to third embodiments.

FIGS. 5A and 5B show the configuration of the semiconductor device according to a fourth embodiment. FIG. 5A is a top view and FIG. 5B is a cross-sectional view taken along line X-X′ of FIG. 5A.

As shown in FIGS. 5A and 5B, the semiconductor device of the fourth embodiment is formed by fixing a semiconductor element 13 with, for example, conductive adhesive on the mounting region 4 in the packages for a semiconductor device according to the first to third embodiments, electrically connecting the semiconductor element 13 and the connected region 5 via conductive materials including a wire 14, and forming molding resin 15 in a region surrounded by the resin part 3 and the lead frames 1 and 2 such that the semiconductor element 13 and the wire 14 are molded with the molding resin 15. In FIGS. 1A to 1C, the backsides of the lead frames 1 and 2 are coated with resin, whereas in FIGS. 5A and 5B, the backsides of the lead frames 1 and 2 are not coated with resin, thereby quickly releasing heat generated in an operation of the semiconductor element 13. Additionally, the semiconductor device can be reduced in thickness.

An optical semiconductor device may be formed using the package for an optical semiconductor device, an optical semiconductor element serving as the semiconductor element 13, and translucent resin serving as the molding resin 15.

What is claimed is:

1. A package for a semiconductor device, comprising:
at least one first lead frame having an element mounting region on a major surface;
at least one second lead frame that has a connected region on a major surface and is electrically isolated;
at least one through hole that is provided on at least one of the first lead frame and the second lead frame and penetrates the major surface and a back side of the lead frame with respect to the major surface;
a resin part formed on the major surfaces of the first lead frame and the second lead frame so as to open the element mounting region and the connected region; and
holding resin provided at least partially on sides of the first and second lead frames with respect to the major surfaces, in a gap between the first and second lead frames, and in the through hole,
wherein the resin part covers at least a part of the through hole, and the resin part and the holding resin are made of the same material.

2. The package for a semiconductor device according to claim 1, wherein the holding resin is only provided at least partially on the sides, in the gap, and in the through hole.

3. The package for a semiconductor device according to claim 1, further comprising a first step provided around the through hole to have a thin portion on the lead frame.

4. The package for a semiconductor device according to claim 3, further comprising a second step provided at least partially on the sides and around the gap to have a thin portion on the lead frame.

5. The package for a semiconductor device according to claim 4, wherein one of the first step and the second step includes discontinuously formed steps.

6. The package for a semiconductor device according to claim 4, wherein one of the first step and the second step includes a continuously formed step.

7. The package for a semiconductor device according to claim 1, wherein the holding resin exposed from the gap between the first and second lead frames in an opening of the resin part has a surface including asperities.

8. The package for a semiconductor device according to claim 7, wherein the asperities include projections.

9. The package for a semiconductor device according to claim 7, wherein the asperities include recesses.

10. The package for a semiconductor device according to claim 7, wherein the asperities include at least one groove.

11. The package for a semiconductor device according to claim 1, wherein the resin part is a reflector and the package is a package for an optical semiconductor device.

12. A method of manufacturing a package for a semiconductor device, the method comprising:
a lead frame processing step of forming at least one through hole on a lead frame, the through hole penetrating a major surface of the lead frame and a back side of the lead frame with respect to the major surface;
a die step of placing the lead frame in a die; and
a resin injecting step of injecting resin into the die,
wherein the resin is injected onto the major surface of the lead frame at least through the through hole.

13. The method of manufacturing a package for a semiconductor device according to claim 12, wherein in the lead frame processing step, a step is additionally formed around the through hole to have a thin portion on the lead frame.

14. The method of manufacturing a package for a semiconductor device according to claim 13, wherein the step is formed by coining.

15. A semiconductor device comprising:
the package for a semiconductor device according to claim 1;
a semiconductor element mounted on the element mounting region;
a conductive material electrically connecting the semiconductor element and the connected region; and
molding resin that molds inside of an opening of the resin part.

16. A semiconductor device comprising:
the package for a semiconductor device according to claim 11;
an optical semiconductor element mounted on the element mounting region;
a conductive material electrically connecting the optical semiconductor element and the connected region; and
translucent resin that molds inside of an opening of the reflector,
wherein the semiconductor device is an optical semiconductor device.
